(19) United States
(12) Patent Application Publication
(10) Pub. No.: US 2025/0267972 A1
(43) Pub. Date: Aug. 21, 2025

(54) IMAGE SENSOR AND METHOD OF FABRICATING THE SAME

(71) Applicant: SAMSUNG ELECTRONICS CO., LTD., Suwon-si (KR)

(72) Inventors: KEEWON KIM, Suwon-si (KR); Ki Joong Yoon, Suwon-si (KR); Jongmin Jeon, Suwon-si (KR); Jaesung Hur, Suwon-si (KR)

(73) Assignee: SAMSUNG ELECTRONICS CO., LTD., Suwon-si (KR)

(21) Appl. No.: 19/011,138

(22) Filed: Jan. 6, 2025

(30) Foreign Application Priority Data
Feb. 20, 2024 (KR) 10-2024-0024374

(51) Int. Cl. H10F 39/00; H10F 39/12

(52) U.S. Cl. CPC H10F 39/811; H10F 39/011; H10F 39/199; H10F 39/8063; H10F 39/807

(57) ABSTRACT

An image sensor includes a substrate having first and second surfaces opposite to each other, an antireflection structure on the second surface, a substrate isolation part separating the substrate, and a backside contact in a backside contact trench that penetrates the antireflection structure. The backside contact includes a contact conductive pattern on a sidewall of the backside contact trench, and a contact metal pattern on the contact conductive pattern. The antireflection structure includes a first dielectric layer, a high-refractive layer on the first dielectric layer, and a contact break between the high-refractive layer and the backside contact.

### CROSS-REFERENCE TO RELATED APPLICATION

This U.S. nonprovisional application claims priority under 35 U.S.C § 119 to Korean Patent Application No. 10-2024-0024374 filed on Feb. 20, 2024 in the Korean Intellectual Property Office, the disclosure of which is herein incorporated by reference in its entirety.

### BACKGROUND

One or more example embodiments of the disclosure relate to an image sensor and a method of fabricating the same, and more particularly, to a complementary metal oxide semiconductor (CMOS) image sensor and a method of fabricating the same.

An image sensor is a semiconductor device to transform optical images into electrical signals. Recent advances in computer and communication industries have led to strong demands in high performance image sensors in various consumer electronic devices such as digital cameras, camcorders, PCSs (Personal Communication Systems), game devices, security cameras, medical micro-cameras, etc.

As semiconductor devices become highly integrated, image sensors may also be highly integrated. Thus, the size of individual pixels may also be reduced. Accordingly, there is a need for an image sensor with reduced crosstalk and increased sensitivity in a fine area.

In an image sensor in which a high-refractive material is applied to a bottom antireflective layer (BARL), there is a need for a reduction in leakage current from adjacent wiring lines.

### SUMMARY

Some embodiments of the disclosure provide an image sensor advantageous to pixel miniaturization and a method of fabricating the same.

Some embodiments of the disclosure provide an image sensor with increased sensitivity and a method of fabricating the same.

Some embodiments of the disclosure provide an image sensor favorable for high integration and a method of fabricating the same.

According to some embodiments of the disclosure, an image sensor may comprise: a substrate that has a first surface and a second surface that are opposite to each other, the substrate including a pixel array area and an edge area; an antireflection structure on the second surface; a substrate isolation part in the substrate, the substrate isolation part separating the substrate; a microlens on the antireflection structure; and a backside contact in a backside contact trench, the backside contact trench penetrating the antireflection structure, the backside contact being in contact with the substrate isolation part. The backside contact may include: a contact conductive pattern on a sidewall of the backside contact trench; and a contact metal pattern on the contact conductive pattern. The antireflection structure may include: a first dielectric layer; a high-refractive layer on the first dielectric layer; and a contact break between the high-refractive layer and the backside contact.

According to some embodiments of the disclosure, an image sensor may comprise: a substrate that has a first surface and a second surface that are opposite to each other, the substrate including a pixel array area and an edge area; an antireflection structure on the second surface; a microlens on the antireflection structure; a first backside via pattern that penetrates the antireflection structure and the substrate on the edge area; a first interlayer dielectric layer on the first surface of the substrate; a first interlayer wiring line in the first interlayer dielectric layer; a second interlayer dielectric layer on or below the first interlayer dielectric layer; and a second interlayer wiring line in the second interlayer dielectric layer. The antireflection structure may include: a first dielectric layer; a high-refractive layer on the first dielectric layer; and a first via break between the high-refractive layer and the first backside via pattern.

According to some embodiments of the disclosure, an image sensor may comprise: a substrate that has a first surface and a second surface that are opposite to each other, the substrate including a pixel array area and an edge area; a transfer gate on the first surface; an antireflection structure on the second surface; a substrate isolation part in the substrate, the substrate isolation part separating the substrate; a microlens on the antireflection structure; and a backside contact in a backside contact trench, the backside contact trench penetrating the antireflection structure, the backside contact being in contact with the substrate isolation part. The backside contact may include: a contact conductive pattern on a sidewall of the backside contact trench; and a contact metal pattern on the contact conductive pattern. The antireflection structure may include: a first dielectric layer; a high-refractive layer on the first dielectric layer; and a contact break between the high-refractive layer and the backside contact. The backside contact may include a contact protrusion that protrudes toward the contact break.

### BRIEF DESCRIPTION OF DRAWINGS

Example embodiments will be more clearly understood from the following detailed description taken in conjunction with the accompanying drawings.

FIG. 1 illustrates a simplified block diagram showing an image sensor according to some embodiments of the disclosure.

FIG. 2 illustrates a circuit diagram showing an active pixel sensor array of an image sensor according to some embodiments of the disclosure.

FIG. 3 illustrates a plan view showing an image sensor according to some embodiments of the disclosure.

FIG. 4 illustrates a cross-sectional view taken along line A-A′ of FIG. 3.

FIG. 5 illustrates an enlarged view showing section X of FIG. 4.

FIG. 6 illustrates an enlarged plan view showing section Y of FIG. 4.

FIG. 7A illustrates an enlarged cross-sectional view of section X of FIG. 4, showing an image sensor according to some embodiments of the disclosure.

FIG. 7B illustrates an enlarged cross-sectional view of section Y of FIG. 4, showing an image sensor according to some embodiments of the disclosure.

FIGS. 8 to 13C illustrate cross-sectional views corresponding to line A-A′ of FIG. 3 and sections X and Y of FIG. 4, showing a method of fabricating an image sensor according to some embodiments of the disclosure.

### DETAILED DESCRIPTION

The following will now describe in detail some example embodiments of the disclosure with reference to the accompanying drawings.

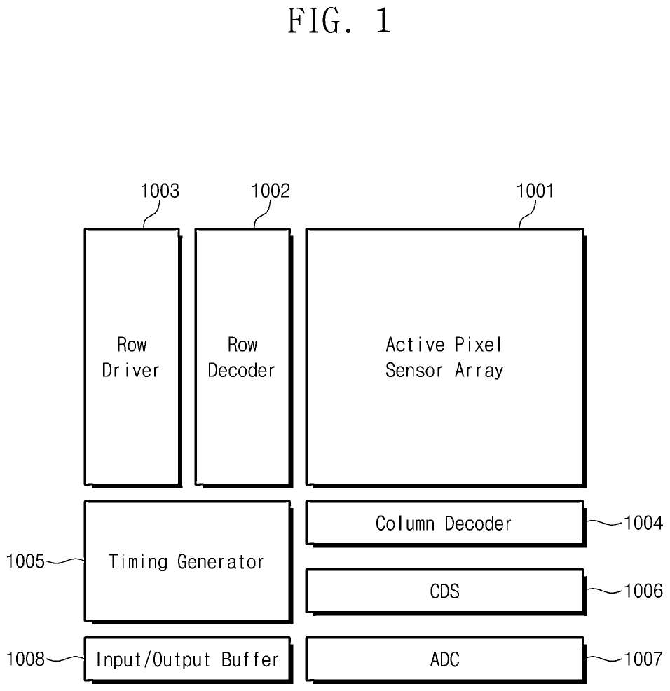

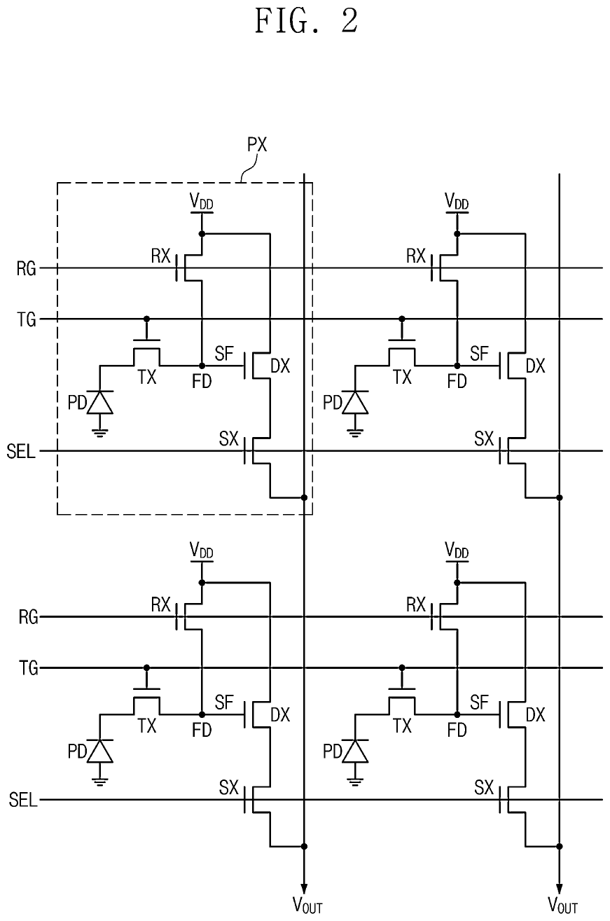

FIG. 1 illustrates a simplified block diagram showing an image sensor according to some embodiments of the disclosure.

Referring to FIG. 1, an image sensor may include an active pixel sensor array 1001, a row decoder 1002, a row driver 1003, a column decoder 1004, a timing generator 1005, a correlated double sampler (CDS) 1006, an analog-to-digital converter (ADC) 1007, and an input/output buffer 1008.

The active pixel sensor array 1001 may include a plurality of two-dimensionally arranged unit pixels, each of which is configured to convert optical signals into electrical signals. The active pixel sensor array 1001 may be driven by a plurality of driving signals such as a pixel selection signal, a reset signal, and a charge transfer signal from the row driver 1003. The correlated double sampler 1006 may be provided with the converted electrical signals.

The row driver 1003 may provide the active pixel sensor array 1001 with several driving signals for driving several unit pixels in accordance with a decoded result obtained from the row decoder 1002. When the unit pixels are arranged in a matrix shape, the driving signals may be provided for each row.

The timing generator 1005 may provide timing and control signals to the row decoder 1002 and the column decoder 1004.

The correlated double sampler 1006 may receive the electrical signals generated from the active pixel sensor array 1001, and may hold and sample the received electrical signals. The correlated double sampler 1006 may perform a double sampling operation to sample a specific noise level and a signal level of the electrical signal, and then may output a difference level corresponding to a difference between the noise and signal levels.

The analog-to-digital converter 1007 may convert analog signals, which correspond to the difference level received from the correlated double sampler 1006, into digital signals, and then output the converted digital signals.

The input/output buffer 1008 may latch the digital signals and then sequentially output the latched digital signals to an image signal processing unit (not shown) in response to the decoded result obtained from the column decoder 1004.

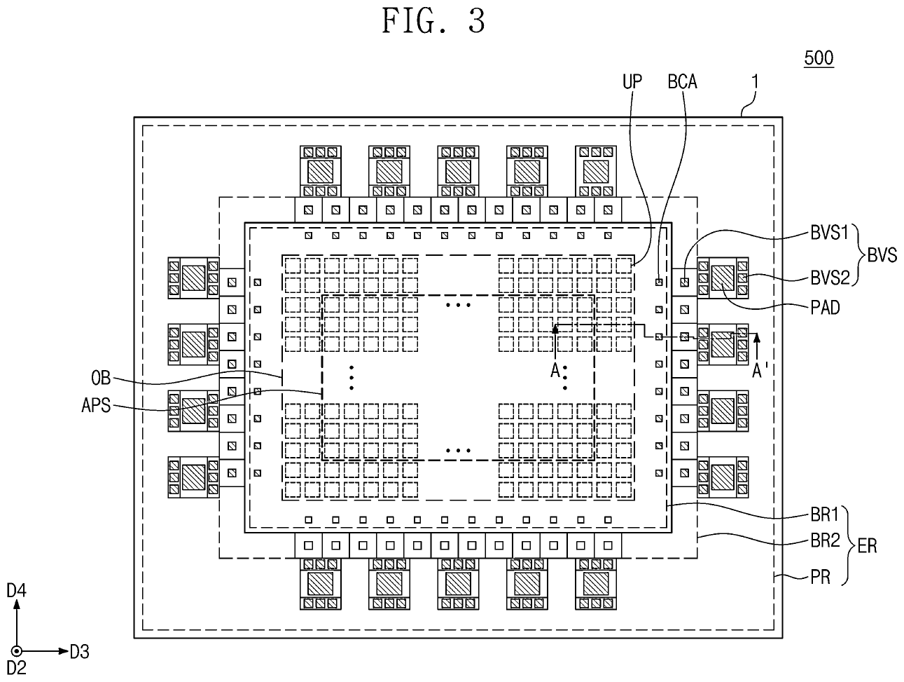

FIG. 2 illustrates a circuit diagram showing an active pixel sensor array of an image sensor according to some embodiments of the disclosure.

Referring to FIGS. 1 and 2, the active pixel sensor array 1001 may include a plurality of pixel regions PX, and the plurality of pixel regions PX may be arranged in a matrix shape. Each pixel region PX may include a transfer transistor TX. Each pixel region PX may further include logic transistors RX, SX, and DX. The logic transistors RX, SX, and DX may include a reset transistor RX, a selection transistor SX, and a source follower transistor DX. The transfer transistor TX may include a transfer gate TG. Each of the pixel regions PX may further include a photoelectric conversion element PD and a floating diffusion region FD. The logic transistors RX, SX, and DX may be shared by a plurality of pixel regions PX.

The photoelectric conversion element PD may create and accumulate photo- charges in proportion to an amount of externally incident light. The photoelectric conversion element PD may include a photodiode, a phototransistor, a photogate, a pinned photodiode, or any combination thereof. The transfer transistor TX may transfer charges generated in the photoelectric conversion element PD into the floating diffusion region FD. The floating diffusion region FD may accumulate and store charges that are generated and transferred from the photoelectric conversion element PD. The source follower transistor DX may be controlled by an amount of photo-charges accumulated in the floating diffusion region FD.

The reset transistor RX may periodically reset the charges accumulated in the floating diffusion region FD. The reset transistor RX may have a drain electrode electrically connected to the floating diffusion region FD and a source electrode electrically connected to a power voltage V_{DD}. When the reset transistor RX is turned on, the floating diffusion region FD may be supplied with the power voltage V_{DD} electrically connected to the source electrode of the reset transistor RX. Accordingly, when the reset transistor RX is turned on, the charges accumulated in the floating diffusion region FD may be exhausted and thus the floating diffusion region FD may be reset.

The source follower transistor DX including a source follower gate SF may serve as a source follower buffer amplifier. The source follower transistor DX may amplify a variation in electrical potential of the floating diffusion region FD and may output the amplified electrical potential to an output line V_{OUT}.

The selection transistor SX including a selection gate SEL may select each row of the pixel region PX to be readout. When the selection transistor SX is turned on, the power voltage V_{DD} may be applied to a drain electrode of the source follower transistor DX.

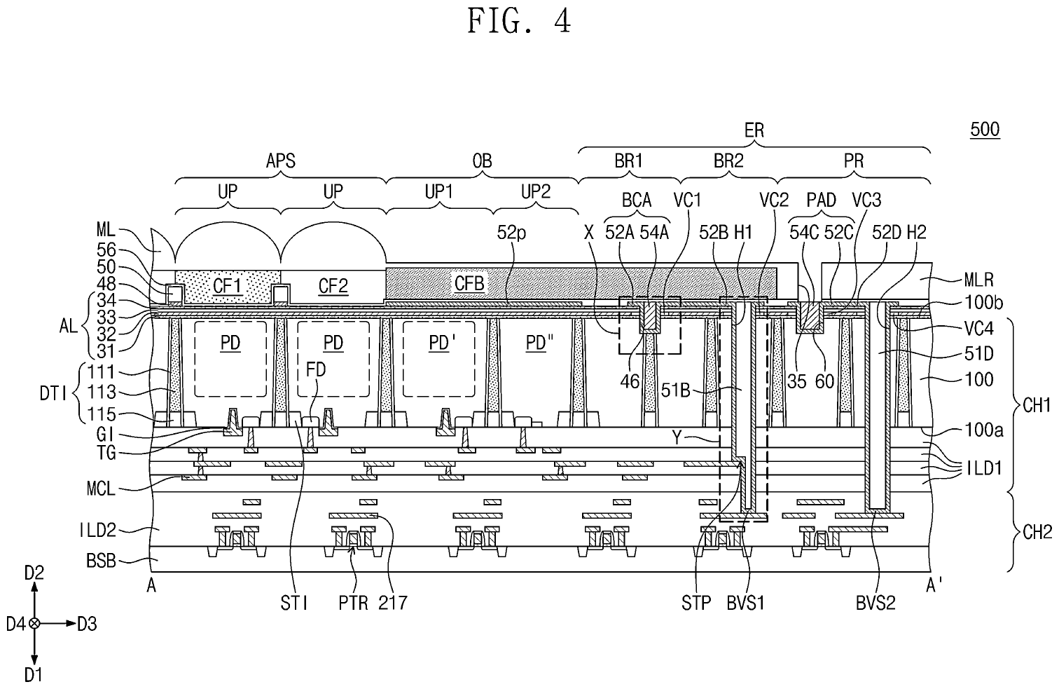

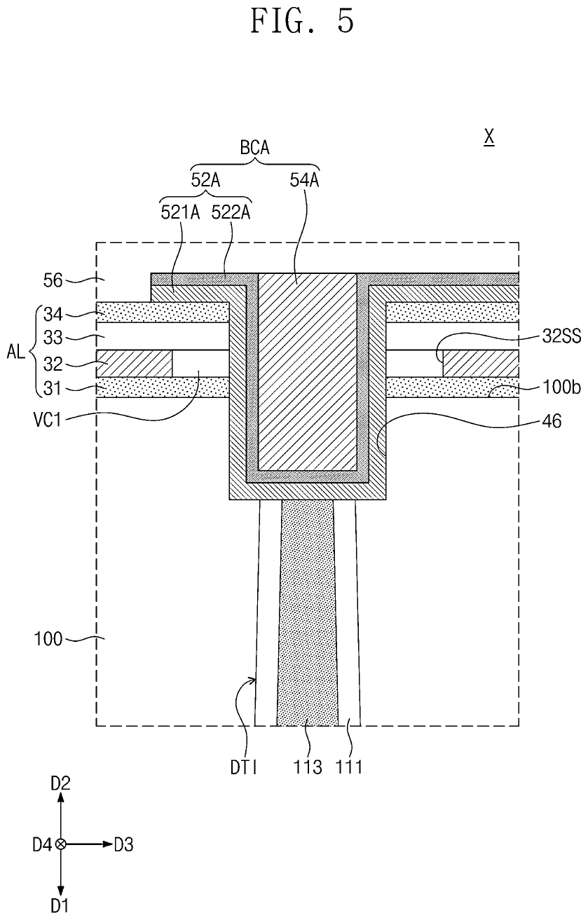

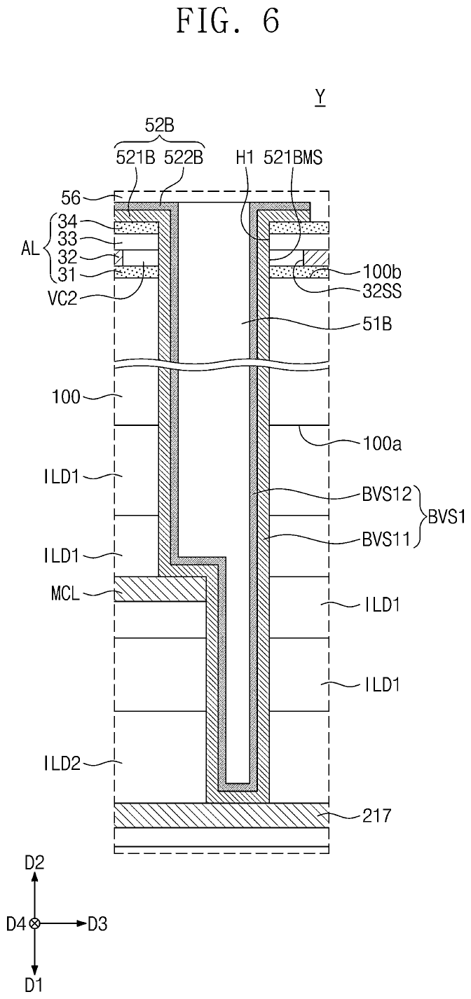

FIG. 3 illustrates a plan view showing an image sensor according to some embodiments of the disclosure. FIG. 4 illustrates a cross-sectional view taken along line A-A′ of FIG. 3. FIG. 5 illustrates an enlarged view showing section X of FIG. 4. FIG. 6 illustrates an enlarged cross-sectional view showing section Y of FIG. 4.

Referring to FIGS. 3 and 4, an image sensor 500 according to some embodiments of the disclosure may have a structure in which first and second sub-chips CH1 and CH2 are bonded to each other. The first sub-chip CH1 may be disposed on the second sub-chip CH2. The first sub-chip CHI may include a substrate 100. The substrate 100 may be, for example, a single-crystalline silicon wafer, a silicon epitaxial layer, or a silicon-on-insulator (SOI) substrate. The substrate 100 may be doped with impurities having a first conductivity type. For example, the first conductivity type may be a p-type.

The substrate 100 may have a first surface 100a and a second surface 100b that are opposite to each other. The first surface 100a may face a second direction D2, and the second surface 100b may face a first direction D1. The first direction D1 and the second direction D2 may be opposite to each other. The substrate 100 may include a pixel array area APS, an optical black area OB, and an edge area ER.

The pixel array area APS and the optical black area OB may each include a plurality of unit pixels UP. The unit pixels UP may be arranged along a third direction D3 and a fourth direction D4. The optical black area OB may surround the pixel array area APS. The edge area ER may surround the pixel array area APS and the optical black area OB. The edge area ER may include a contact region BR1, a via region BR2, and a pad region PR. The via region BR2 may be positioned between the contact region BR1 and the pad region PR. The pad region PR may be positioned on an outermost section of the edge area ER.

On the pixel array area APS and the optical black area OB, the substrate 100 may be provided therein with a substrate isolation part DTI that separates and/or limits the unit pixels UP on the pixel array area APS and separates and/or limits regions of the substrate 100 on the optical black area OB. The substrate isolation part DTI may extend to the contact region BR1 of the edge area ER. The substrate isolation part DTI may have a mesh shape when viewed in plan.

On the edge area ER, the substrate 100 may be provided on its second surface 100b with backside contacts BCA, backside via patterns BVS1 and BVS2, and backside conductive pads PAD. The backside via patterns BVS1 and BVS2 may include a first backside via pattern BVS1 and a second backside via pattern BVS2. One or more of column and row signals may be transmitted between the first and second sub-chips CH1 and CH through the backside via patterns BVS1 and BVS2.

The substrate isolation part DTI may be positioned in the substrate 100. The substrate isolation part DTI may separate the unit pixels UP from each other. The substrate isolation part DTI may penetrate in the second direction D2 through the substrate 100 between the unit pixels UP.

The substrate isolation part DTI may penetrate only a portion of the substrate 100. In this case, the substrate 100 may include a region aligned with the substrate isolation part DTI and doped opposite to a photoelectric conversion element PD which will be discussed below, thereby defining a pixel.

The substrate isolation part DTI may extend from the first surface 100a toward the second surface 100b. When viewed in plan, the substrate isolation part DTI may have a mesh shape in which lines extending in the third and fourth directions D3 and D4 intersect each other. The substrate isolation parts DTI may have a width that decreases in a direction from the first surface 100a toward the second surface 100b of the substrate 100.

The substrate isolation part DTI may extend from the second surface 100b toward the first surface 100a. The substrate isolation part DTI may have a width that decreases in a direction from the second surface 100b toward the first surface 100a of the substrate 100.

The substrate isolation part DTI may include a buried dielectric pattern 115, an isolation dielectric pattern 111, and an isolation conductive pattern 113. The buried dielectric pattern 115 may be interposed between the isolation conductive pattern 113 and a first interlayer dielectric layer ILD1 which will be discussed below. The isolation dielectric pattern 111 may be interposed between the isolation conductive pattern 113 and the substrate 100 and between the buried dielectric pattern 115 and the substrate 100.

The buried dielectric pattern 115 and the isolation dielectric pattern 111 may be formed of a dielectric material whose refractive index is different from that of the substrate 100. The buried dielectric pattern 115 and the isolation dielectric pattern 111 may include, for example, silicon oxide. The isolation conductive pattern 113 may be spaced apart from the substrate 100. The isolation conductive pattern 113 may include an impurity-doped polysilicon layer or a silicon-germanium layer. For example, one of boron, phosphorus, and arsenic may be chosen as impurities doped into the polysilicon layer or the silicon-germanium layer. Alternatively, the isolation conductive pattern 113 may include a metal layer.

A shallow device isolation pattern STI may be positioned in the substrate 100. The shallow device isolation pattern STI may extend from the first surface 100a into the substrate 100, and may be disposed in a corresponding one of a plurality of unit pixels UP. The shallow device isolation pattern STI may limit active sections adjacent to the first surface 100a of the substrate 100 on the pixel array area APS. The active sections may be provided for the transistors TX, RX, DX, and SX of FIG. 2.

The unit pixels UP may correspondingly include photoelectric conversion elements PD in the substrate 100. The photoelectric conversion elements PD may be doped with impurities having a second conductivity type opposite to the first conductivity type. The second conductivity type may be, for example, an n-type. The n-type impurities doped in the photoelectric conversion element PD and the p-type impurities doped in the substrate 100 therearound may constitute a PN junction to provide a photodiode.

Referring to FIG. 4, on the unit pixel UP, a transfer gate TG may be disposed on the first surface 100a of the substrate 100. A portion of the transfer gate TG may extend into the substrate 100. The transfer gate TG may have a vertical type. Alternatively, the transfer gate TG may be a planar type that does not extend into the substrate 100. A gate dielectric layer GI may be interposed between the transfer gate TG and the substrate 100. A floating diffusion region FD may be disposed in the substrate 100 on one side of the transfer gate TG. The floating diffusion region FD may be doped with impurities having, for example, the second conductivity type.

A first unit pixel UP1 and a second unit pixel UP2 may be disposed on the optical black area OB of the substrate 100. On the first unit pixel UP1, a black photoelectric conversion element PD′ may be provided in the substrate 100. On the second unit pixel UP2, a dummy element PD″ may be provided in the substrate 100. The black photoelectric conversion element PD′ may be doped with impurities having, for example, the second conductivity type different from the first conductivity type. The second conductivity type may be, for example, an n-type. The black photoelectric conversion element PD′ may have a similar structure to that of the photoelectric conversion element PD, but may not perform the same operation (e.g., conversion of light into electrical signals) as that of the photoelectric conversion element PD. A signal generated from the black photoelectric conversion element PD′ may be used to produce a dark level reference signal. The dummy element PD″ may not be doped with impurities. A signal generated from the dummy element PD″ may be used as information to remove subsequent process noise.

The substrate 100 may be provided on its first surface 100a with a first interlayer dielectric layer ILD1 and first interlayer wiring lines MCL.

The first interlayer dielectric layer ILD1 may be provided on and cover the first surface 100a of the substrate 100. The first interlayer dielectric layer ILD1 may be a silicon oxide layer, a silicon nitride layer, a silicon oxynitride layer, a porous low-dielectric layer, or a composite layer including at least one of any combination thereof. The first interlayer wiring lines MCL may be provided in the first interlayer dielectric layer ILD1. The floating diffusion region FD may be electrically connected to the first interlayer wiring lines MCL.

A second interlayer dielectric layer ILD2 may be provided on or underneath the first interlayer dielectric layer ILD1. Second interlayer wiring lines 217 may be provided in the second interlayer dielectric layer ILD2. The second interlayer dielectric layer ILD2 may be provided with peripheral transistors PTR therein.

A sub-substrate BSB may be provided on or underneath the second interlayer dielectric layer ILD2. The sub-substrate BSB may be provided therein with circuits that constitute blocks other than the active pixel sensor array 1001 of FIG. 1.

An antireflection structure AL may be provided on the second surface 100b of the substrate 100. The antireflection structure AL may cover the second surface 100b.

Light-shield patterns 48 may be disposed on the antireflection structure AL. Low-refractive patterns 50 may be correspondingly disposed on the light-shield patterns 48. The light-shield pattern 48 and the low-refractive pattern 50 may overlap the substrate isolation part DTI and have a grid shape when viewed in plan. The light-shield pattern 48 may include, for example, titanium. The low-refractive patterns 50 may have the same thickness and include the same organic material. The low-refractive patterns 50 may have a refractive index less than that of color filters CF1 and CF2 which will be discussed below. The light-shield pattern 48 and the low-refractive pattern 50 may prevent crosstalk between neighboring unit pixels UP.

A protection layer 56 may be provided on the low-refractive pattern 50. The protection layer 56 may conformally cover the low-refractive pattern 50.

On the pixel array area APS, color filters CF1 and CF2 may be disposed between the low-refractive patterns 50. The color filters CF1 and CF2 may each have one of blue, green, and red colors. Alternatively, the color filters CF1 and CF2 may have different colors such as cyan, magenta, or yellow. In an image sensor according to the present embodiment, the color filters CF1 and CF2 may be arranged in Bayer pattern. Alternatively, the color filters CF1 and CF2 may be arranged in one of 2×2 Tetra pattern, 3×3 Nona pattern, and 4×4 Hexadeca pattern.

On the pixel array area APS, microlenses ML may be disposed on the color filters CF1 and CF2. The microlenses ML may have edges in contact with and connected to each other.

On the optical black area OB, an optical black liner 52p may be disposed. The optical black liner 52p may include a conductive material. The optical black liner 52p may have a single-layered or multi-layered structure including at least one selected from a titanium layer, a titanium nitride layer, and a tungsten layer.

On the edge area ER, an optical black pattern CFB may be provided. The optical black pattern CFB may include, for example, the same material as that of a blue color filter.

On the edge area ER, a lens residual layer MLR may be disposed on the optical black pattern CFB. The lens residual layer MLR may include the same material as that of the microlenses ML. On the pad region PR, the lens residual layer MLR may have an opening 35 that exposes the backside conductive pad PAD.

The antireflection structure AL may include a first dielectric layer 31, a high-refractive layer 32 on the first dielectric layer 31, a second dielectric layer 33 on the high-refractive layer 32, a third dielectric layer 34 on the second dielectric layer 33, a contact break VC1 between the high-refractive layer 32 and the backside contact BCA, a first via break VC2 between the high-refractive layer 32 and the first backside via pattern BVS1, a pad break VC3 between the backside conductive pad PAD and the high-refractive layer 32, and a second via break VC4 between the second backside via pattern BVS2 and the high-refractive layer 32. The first, second, and third dielectric layers 31, 33, and 34 may include different materials from each other.

The first dielectric layer 31 may be in contact with the second surface 100b of the substrate 100. The first dielectric layer 31 may include, for example, aluminum oxide. The second dielectric layer 33 may include, for example, silicon, silicon oxide, or plasma enhanced silicon oxide (PEOX). The third dielectric layer 34 may include, for example, hafnium oxide. The third dielectric layer 34 may serve as an etch stop layer.

The high-refractive layer 32 may include titanium oxide. For example, the high-refractive layer 32 may include TiO₂.

The substrate 100 may have a substrate refractive index (n0), the first dielectric layer 31 may have a first refractive index (n1), the high-refractive layer 32 may have a second refractive index (n2), and the second dielectric layer 33 may have a third refractive index (n3).

The substrate refractive index (n0) may be greater than the first refractive index (n1). The second refractive index (n2) of the high-refractive layer 32 may be greater than the third refractive index (n3) of the second dielectric layer 33.

The substrate refractive index (n) may range, for example, from about 4.0 to about 4.4. The first refractive index (n1) may range from about 2.0 to about 3.0. The second refractive index (n2) may range from about 2.2 to about 2.8. The third refractive index (n3) may range from about 1.0 to about 1.9. As used herein, the term “about” will be understood as referring to an approximate range of a numerical value by a person of ordinary skill in the art and will vary in some extent depending on the context in which it is used. For example, “about” may mean plus or minus a certain percentage (e.g., 10% or less) of a particular range or value. However, these are merely examples and the disclosure is not limited thereto.

On the contact region BR1, the backside contact BCA may be disposed in a backside contact trench 46 that penetrates the antireflection structure AL and a portion of the substrate 100. The backside contact BCA may be in contact with the substrate isolation part DTI. The backside contact BCA may include a contact conductive pattern 52A on a sidewall of the backside contact trench 46 and a contact metal pattern 54A on the contact conductive pattern 52A.

The contact conductive pattern 52A may conformally cover an inner wall of the backside contact trench 46. The contact conductive pattern 52A may be in contact with the first dielectric layer 31, the second dielectric layer 33, and the third dielectric layer 34. The contact conductive pattern 52A may be spaced apart from the high-refractive layer 32.

The contact metal pattern 54A may fill the backside contact trench 46. The contact metal pattern 54A may include, for example, aluminum.

The backside contact BCA may be in contact with the isolation conductive pattern 113 of the substrate isolation part DTI. A negative bias may be applied through the backside contact BCA to the isolation conductive pattern 113 of the substrate isolation part DTI. The isolation conductive pattern 113 may serve as a common bias line. Therefore, holes possibly present on a surface of the substrate 100 in contact with the substrate isolation part DTI may be trapped to improve dark current properties.

The contact break VC1 may be provided between the contact conductive pattern 52A and the high-refractive layer 32.

In an embodiment, the contact break VC1 may have a configuration in which an empty space is provided therein. The contact break VC1 may form an empty space therein. The contact break VC1 may include an empty space therein.

In an embodiment, the contact break VC1 may include a dielectric material. For example, the contact break VC1 may include SiO₂ or Al₂O₃.

Referring to FIG. 5, the contact break VC1 and the backside contact BCA will be illustrated in detail.

The contact conductive pattern 52A of the backside contact BCA may include a first contact conductive pattern 521A in contact with an inner wall of the backside contact trench 46, and may also include a second contact conductive pattern 522A on the first contact conductive pattern 521A. The first contact conductive pattern 521A may be in contact with the first dielectric layer 31, the second dielectric layer 33, and the third dielectric layer 34. The first contact conductive pattern 521A may be in direct contact with the substrate isolation part DTI. The second contact conductive pattern 522A may be in contact with the contact metal pattern 54A. The second contact conductive pattern 522A may be in contact with the protection layer 56.

The first contact conductive pattern 521A and the second contact conductive pattern 522A may include different materials from each other. The first contact conductive pattern 521A may include, for example, titanium or titanium nitride. The second contact conductive pattern 522A may include, for example, tungsten.

The first contact conductive pattern 521A may be spaced apart from the high-refractive layer 32. The contact break VC1 may be provided between the first contact conductive pattern 521A and the high-refractive layer 32.

When the contact break VC1 includes an empty space therein, one sidewall 32SS of the high-refractive layer 32 may be exposed.

The contact break VC1 may be surrounded by the high-refractive layer 32, the second dielectric layer 33, the first dielectric layer 31, and the first contact conductive pattern 521A. The second dielectric layer may be continuously interposed between the backside contact BCA and the first backside via pattern BVS1.

Referring back to FIG. 4, on the via region BR2, the first backside via patterns BVS1 may be disposed on the second surface 100b of the substrate 100. On the pad region PR, the backside conductive pads PAD and the second backside via patterns BVS2 may be disposed on the second surface 100b of the substrate 100. Several of the second backside via patterns BVS2 may form a group, and a plurality of groups may be disposed around corresponding backside conductive pads PAD. An external signal may be input and/or output through the backside conductive pads PAD. The backside conductive pads PAD may become interfaces of external signals.

The backside conductive pad PAD may be disposed in a backside pad trench 60. The backside conductive pad PAD may include a pad conductive pattern 52C and a pad metal pattern 54C. The pad conductive pattern 52C may conformally cover a lateral surface and a bottom surface of the backside pad trench 60.

The pad conductive pattern 52C may include the same material as that of the contact conductive pattern 52A and have the same thickness as that of the contact conductive pattern 52A. The pad conductive pattern 52C may have a single-layered or multi-layered structure of at least one selected from a titanium layer, a titanium nitride layer, and a tungsten layer. The pad metal pattern 54C may include, for example, aluminum. The pad metal pattern 54C may fill the backside pad trench 60.

The pad break VC3 may be provided between the pad conductive pattern 52C and the high-refractive layer 32. The pad break VC3 may be similar to the contact break VC1. The pad break VC3 may include an empty space therein or include a dielectric material such as SiO₂ or Al₂O₃. The pad break VC3 may separate the pad conductive pattern 52C and the high-refractive layer 32 from each other.

The first via break VC2 may be provided between the first backside via pattern BVS1 and the high-refractive layer 32. The first via break VC2 may be similar to the contact break VC1. The first via break VC2 may include an empty space therein or include a dielectric material such as SiO₂ or Al₂O₃. The first via break VC2 may separate the first backside via pattern BVS1 and the high-refractive layer 32 from each other.

The second via break VC4 may be provided between the second backside via pattern BVS2 and the high-refractive layer 32. The second via break VC4 may be similar to the contact break VC1. The second via break VC4 may include an empty space therein or include a dielectric material such as SiO₂ or Al₂O₃. The second via break VC4 may separate the second backside via pattern BVS2 and the high-refractive layer 32 from each other.

The backside contact BCA and the first backside via pattern BVS1 may be electrically connected through a connection conductive pattern 52B.

The first backside via pattern BVS1 may be provided on the second surface 100b of the substrate 100. The first backside via pattern BVS1 may be disposed in a first backside via hole H1 that penetrates the antireflection structure AL and a portion of the substrate 100. The first backside via pattern BVS1 may conformally cover a sidewall of the first backside via hole H1.

The first backside via pattern BVS1 may be in contact with the first dielectric layer 31, the second dielectric layer 33, and the third dielectric layer 34. The first backside via pattern BVS1 may be spaced apart from the high-refractive layer 32.

A first low-refractive protection pattern 51B may be disposed on the first backside via pattern BVS1. The first low-refractive protection pattern 51B may have a refractive index less than that of the color filters CF1 and CF2. For example, the first low-refractive protection pattern 51B may have a refractive index equal to or less than about 1.3.

Although not shown, a low-refractive capping pattern (not shown) may be disposed on the first low-refractive protection pattern 51B. In this case, the first low-refractive protection pattern 51B may have a concave top surface.

The first backside via pattern BVS1 and the contact conductive pattern 52A may be electrically connected through the connection conductive pattern 52B. The connection conductive pattern 52B may be disposed on the third dielectric layer 34, and may be placed between the first backside via pattern BVS1 and the contact conductive pattern 52A. The first backside via pattern BVS1, the connection conductive pattern 52B, and the contact conductive pattern 52A may be continuous. The first backside via pattern BVS1 may electrically connect the first interlayer wiring lines MCL to the second interlayer wiring lines 217.

The first backside via pattern BVS1 may include a stepwise part STP. On the stepwise part STP, the first backside via pattern BVS1 may be electrically connected to the first interlayer wiring lines MCL. A bottommost surface of the first backside via pattern BVS1 may be electrically connected to the second interlayer wiring lines 217.

The second backside via pattern BVS2 may be disposed in a second backside via hole H2 that penetrates the antireflection structure AL and a portion of the substrate 100. The second backside via pattern BVS2 may penetrate the antireflection structure AL, the substrate 100, the first interlayer dielectric layer ILD1, and a portion of the second interlayer dielectric layer ILD2. The second backside via pattern BVS2 may be electrically connected to portions of the second interlayer wiring lines 217. Although not shown, the second backside via pattern BVS2 may be electrically connected to portions of the first interlayer wiring lines MCL. The second backside via pattern BVS2 may conformally cover an inner wall and a bottom surface of the second backside via hole H2. The second backside via pattern BVS2 may include the same material as that of the contact conductive pattern 52A and have the same thickness as that of the contact conductive pattern 52A. The second backside via pattern BVS2 may have a single-layered or multi-layered structure of at least one selected from a titanium layer, a titanium nitride layer, and a tungsten layer. One of the second backside via patterns BVS2 may be electrically connected through one of via connection lines 52D to one of the backside conductive pads PAD.

Referring to FIG. 6, the first backside via pattern BVS1 will be illustrated in detail. The first backside via pattern BVS1 may include a first outer via pattern BVS11 that conformally covers an inner wall of the first backside via hole H1, and may also include a first inner via pattern BVS12 on the first outer via pattern BVS11.

The connection conductive pattern 52B may include a first connection conductive pattern 521B connected to the first outer via pattern BVS11, and may also include a second connection conductive pattern 522B electrically connected to the first inner via pattern BVS12.

The first connection conductive pattern 521B may include the same material as that of the first outer via pattern BVS11 and that of the first contact conductive pattern 521A. The first connection conductive pattern 521B may include, for example, titanium or titanium nitride.

The second connection conductive pattern 522B may include the same material as that of the first inner via pattern BVS12 and that of the second contact conductive pattern 522A. The second connection conductive pattern 522B may include, for example, tungsten.

The first outer via pattern BVS11 may be in direct contact with the first interlayer wiring lines MCL and the second interlayer wiring lines 217. The first outer via pattern BVS11 may electrically connect the first interlayer wiring lines MCL to the second interlayer wiring lines 217.

The first via break VC2 may be provided between the first outer via pattern BVS11 and the high-refractive layer 32. The first via break VC2 may separate the first outer via pattern BVS11 and the high-refractive layer 32 from each other.

As discussed above, the high-refractive layer 32 may be spaced apart from the backside contact BCA, the first backside via pattern BVS11, the backside conductive pad PAD, and the second backside via pattern BVS2.

An empty internal space or an insulating material may be included in the contact break VC1 between the high-refractive layer 32 and the backside contact BCA, the first via break VC2 between the high-refractive layer 32 and the first backside via pattern BVS1, the pad break VC3 between the high-refractive layer 32 and the backside conductive pad PAD, and the second via break VC4 between the high-refractive layer 32 and the second backside via pattern BVS2, and thus an electrical short structure may be formed between the high-refractive layer 32 and each of the backside contact BCA, the backside conductive pad PAD, and the first backside via pattern BVS1, and the second backside via pattern BVS2. Accordingly, an image sensor may have improved optical performance.

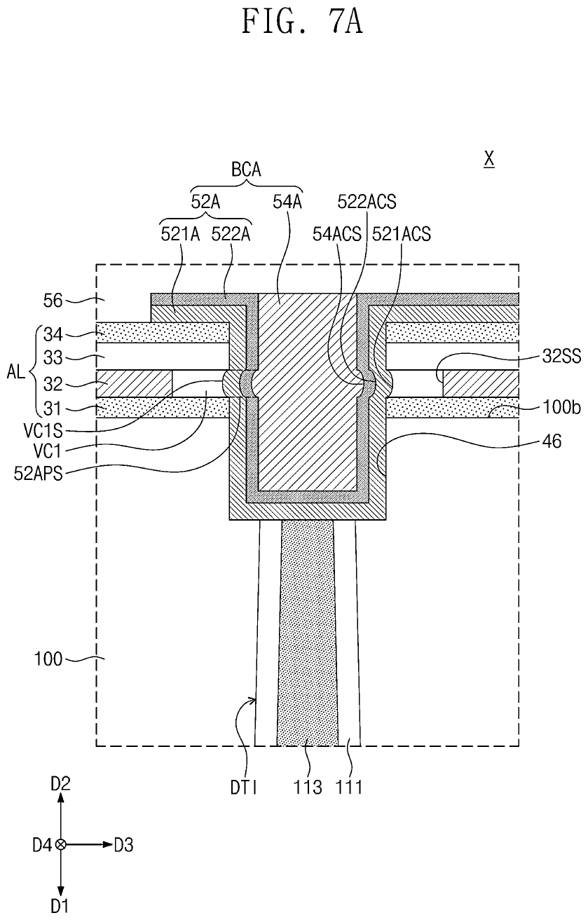

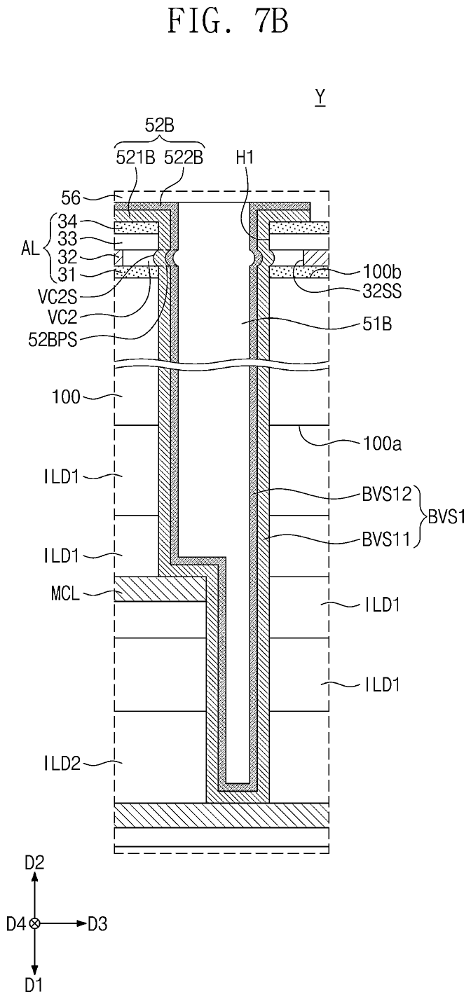

FIG. 7A illustrates an enlarged cross-sectional view of section X of FIG. 4, showing an image sensor according to some embodiments of the disclosure. FIG. 7B illustrates an enlarged cross-sectional view of section Y of FIG. 4, showing an image sensor according to some embodiments of the disclosure. For brevity of description, a repetitive explanation will be omitted.

Referring to FIGS. 7A and 7B, there will be described in detail enlarged cross-sections showing sections X and Y of the image sensor depicted in FIG. 4.

Referring to FIG. 7A, the contact conductive pattern 52A of the backside contact BCA may include a contact protrusion 52APS that protrudes toward the high-refractive layer 32. The contact metal pattern 54A of the backside contact BCA may include a protrusion that protrudes toward the high-refractive layer 32. The contact break VC1 may have a contact break lateral surface VC1S where the contact break VC1 meets the contact conductive pattern 52A, and the contact break lateral surface VC1S may include a curved surface.

The contact conductive pattern 52A may include a first contact conductive pattern 521A in contact with the inner wall of the backside contact trench 46, and may also include a second contact conductive pattern 522A on the first contact conductive pattern 521A.

As the contact metal pattern 54A has a sidewall whose portion protrudes toward the high-refractive layer 32, a lateral surface of the contact metal pattern 54A may include a contact metal curved surface 54ACS.

As the first contact conductive pattern 521A has a sidewall whose portion protrudes toward the high-refractive layer 32, a lateral surface of the first contact conductive pattern 521A may include a first contact conductive lateral surface 521ACS that is curved. The first contact conductive lateral surface 521ACS may be in direct contact with the contact break VC1. When the contact break VC1 includes an empty space therein, the first contact conductive lateral surface 521ACS may be exposed.

As the second contact conductive pattern 522A has a sidewall whose portion protrudes toward the high-refractive layer 32, a lateral surface of the second contact conductive pattern 522A may include a second contact conductive lateral surface 522ACS that is curved. The second contact conductive lateral surface 522ACS may be in contact with the first contact conductive pattern 521A.

Referring to FIG. 7B, the first backside via pattern BVS1 may include a first via protrusion 52BPS that protrudes toward the high-refractive layer 32.

The first outer via pattern BVS11 of the first backside via pattern BVS1 may include a protrusion that protrudes toward the high-refractive layer 32. The first via break VC2 may have a first via break lateral surface VC2S where the first via break VC2 meets the first backside via pattern BVS1, and the first via lateral surface VC2S may include a curved surface.

The first backside via pattern BVS1 may include the first outer via pattern BVS11 that conformally covers an inner wall of the first backside via hole H1, and may also include the first inner via pattern BVS12 on the first outer via pattern BVS11.

As the first backside via pattern BVS1 has a sidewall whose portion protrudes toward the high-refractive layer 32, a lateral surface of the first backside via pattern BVS1 may include a curved surface.

As the first outer via pattern BVS11 has a sidewall whose portion protrudes toward the high-refractive layer 32, a lateral surface of the first outer via pattern BVS11 may include a curved surface. The first outer via pattern BVS11 may be in direct contact with the first via break VC2. When the first via break VC2 includes an empty space therein, the lateral surface of the first outer via pattern BVS11 may be exposed.

As the first inner via pattern BVS12 has a sidewall whose portion protrudes toward the high-refractive layer 32, a lateral surface of the first inner via pattern BVS12 may include a curved surface.

An image sensor according to some embodiments of the disclosure may include the contact break VC1 and the first via break VC2, and the contact conductive pattern 52A and the first backside via pattern BVS1 may have their sidewalls that protrude toward the high-refractive layer 32. The same may apply to the pad break VC3 between the backside conductive pad PAD and the high-refractive layer 32 and the second via break VC4 between the second backside via pattern BVS2 and the high-refractive layer 32.

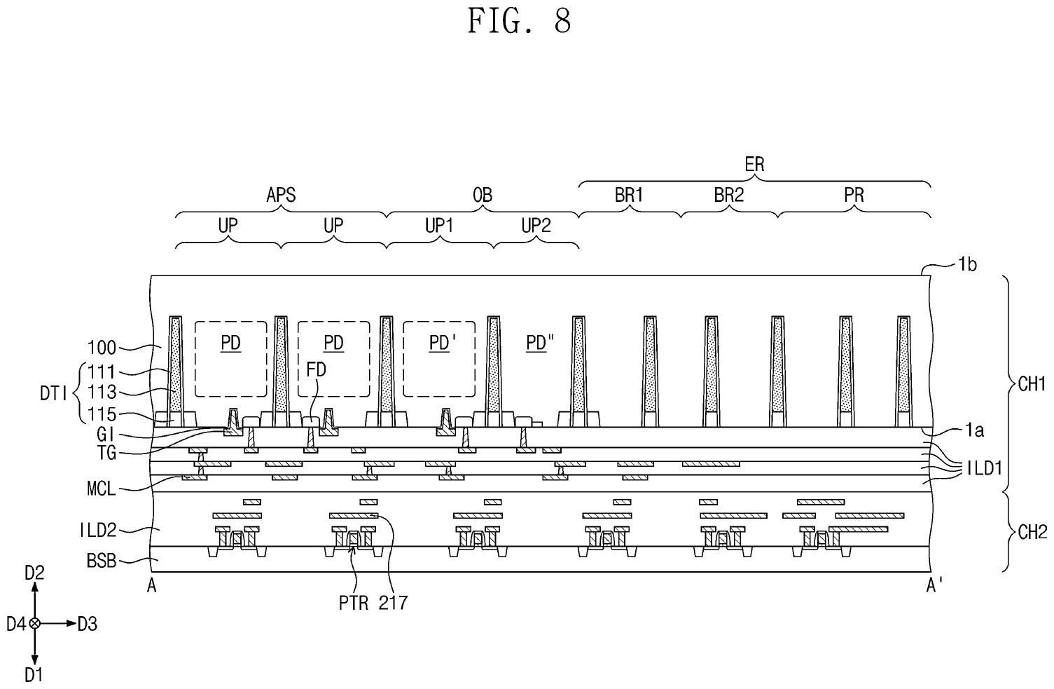

FIGS. 8 to 13C illustrate cross-sectional views corresponding to line A-A′ of FIG. 3 and sections X and Y of FIG. 4, showing a method of fabricating an image sensor according to some embodiments of the disclosure.

Referring to FIG. 8, there may be prepared a second sub-chip CH2 having the structure discussed with reference to FIG. 4 and a first sub-chip CHI bonded to the second sub-chip CH2. The bonding of the first sub-chip CH1 to the second sub-chip CH2 may include connecting the first sub-chip CH1 to the second sub-chip CH2 to allow a first interlayer dielectric layer ILD1 to contact a second interlayer dielectric layer ILD2.

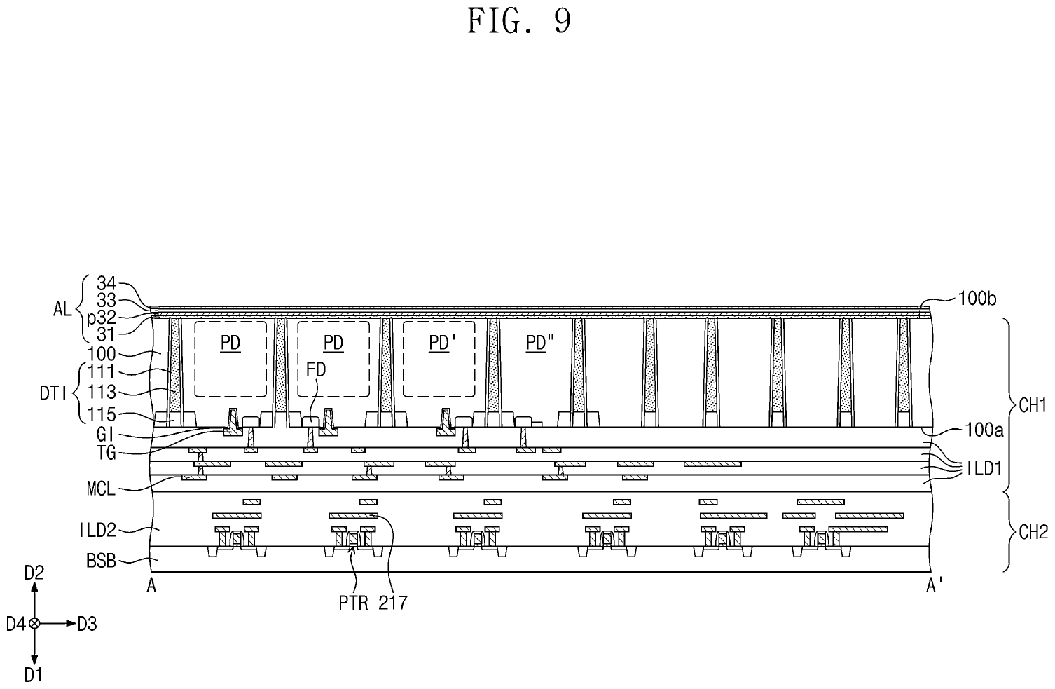

Referring to FIG. 9, a second surface 100b of the substrate 100 may undergo a grinding process to reduce a thickness of the substrate 100 to a desired thickness. In this step, substrate isolation parts DTI may have an exposed top surface. A first dielectric layer 31, a high-refractive layer 32, a second dielectric layer 33, and a third dielectric layer 34 may be conformally formed on the second surface 100b of the substrate 100. An antireflection structure AL may be formed on the second surface 100b of the substrate 100.

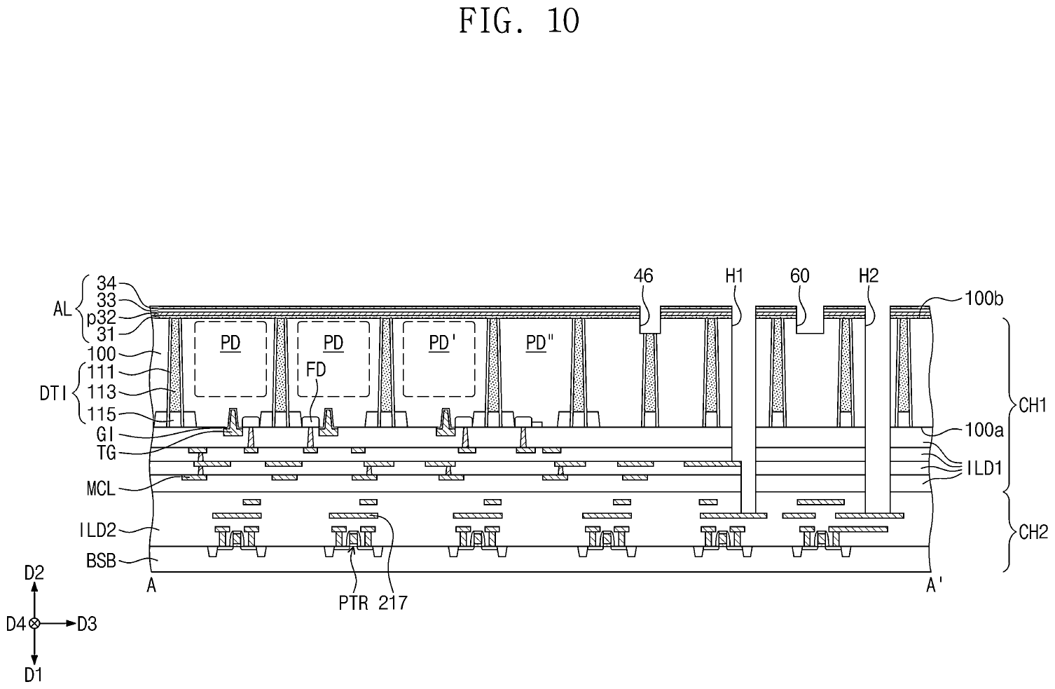

Referring to FIG. 10, the first dielectric layer 31, the high-refractive layer 32, the second dielectric layer 33, the third dielectric layer 34, and a portion of the substrate 100 may be etched to form a backside contact trench 46 and a backside pad trench 60. The backside contact trench 46 may expose the substrate isolation part DTI. The substrate 100 may be exposed by the backside pad trench 60.

The first dielectric layer 31, the high-refractive layer 32, the second dielectric layer 33, the third dielectric layer 34, the substrate 100, the first interlayer dielectric layer ILD1, and a portion of the second interlayer dielectric layer ILD2 may be etched to form a first backside via hole H1 and a second backside via hole H2.

The first backside via hole H1 may expose a first interlayer wiring line MCL and a second interlayer wiring line 217. The second interlayer wiring line 217 may be exposed by the second backside via hole H2.

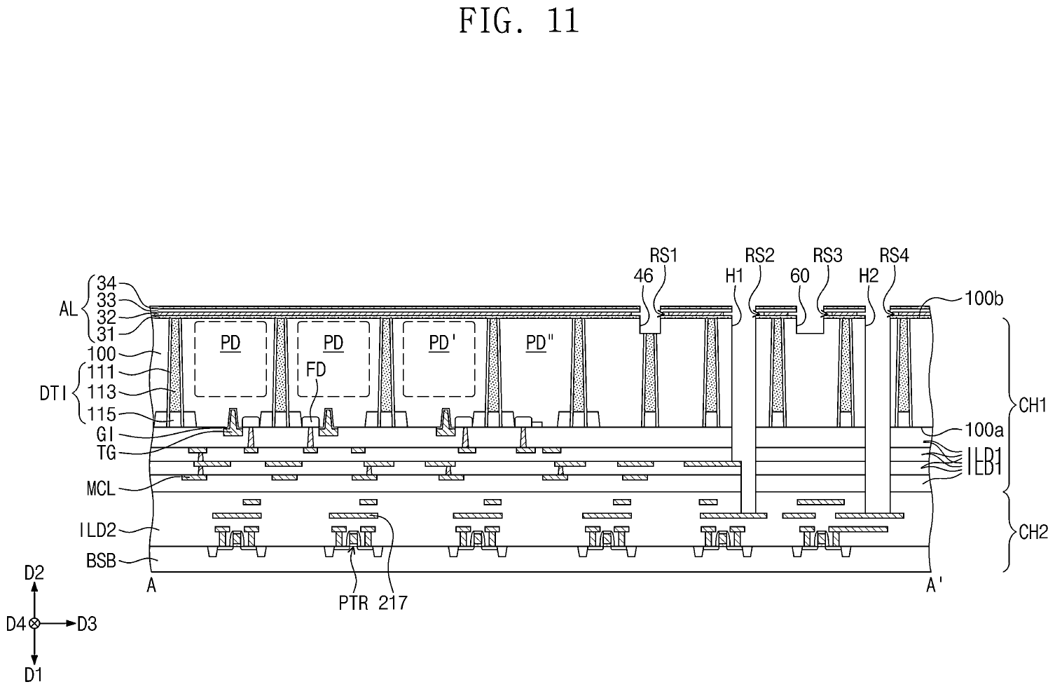

Referring to FIG. 11, a portion of the high-refractive layer 32 may be selectively recessed through the backside contact trench 46. Therefore, a first recess RS1 may be formed.

A portion of the high-refractive layer 32 may be selectively recessed through the first backside via hole H1. Therefore, a second recess RS2 may be formed.

A portion of the high-refractive layer 32 may be selectively recessed through the backside pad trench 60. Therefore, a third recess RS3 may be formed.

A portion of the high-refractive layer 32 may be selectively recessed through the second backside via hole H2. Therefore, a fourth recess RS4 may be formed.

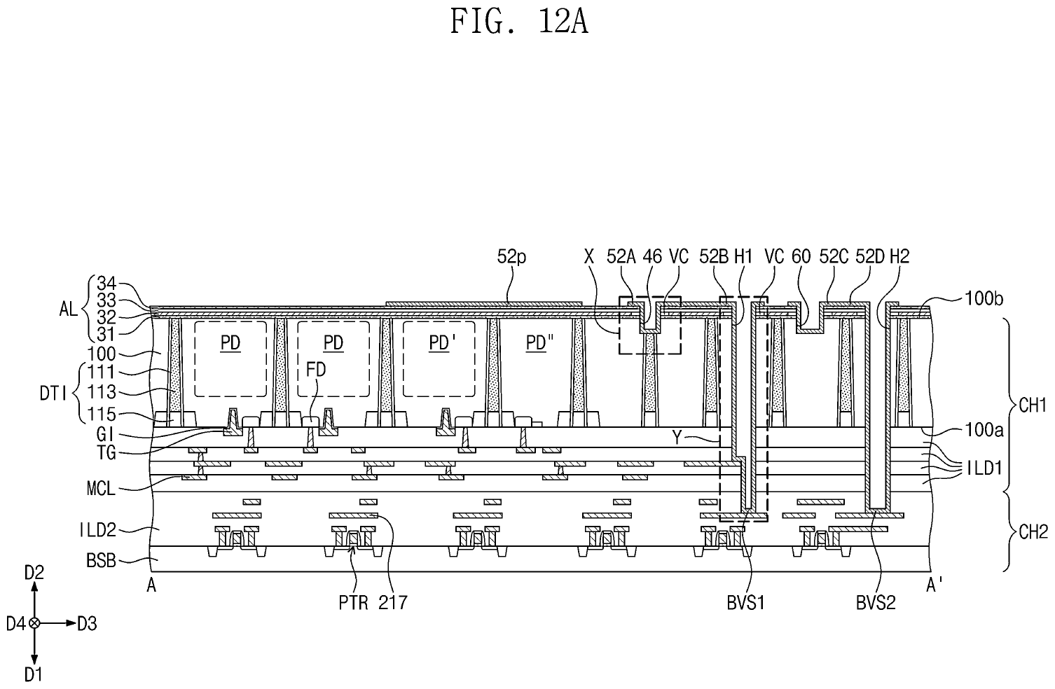

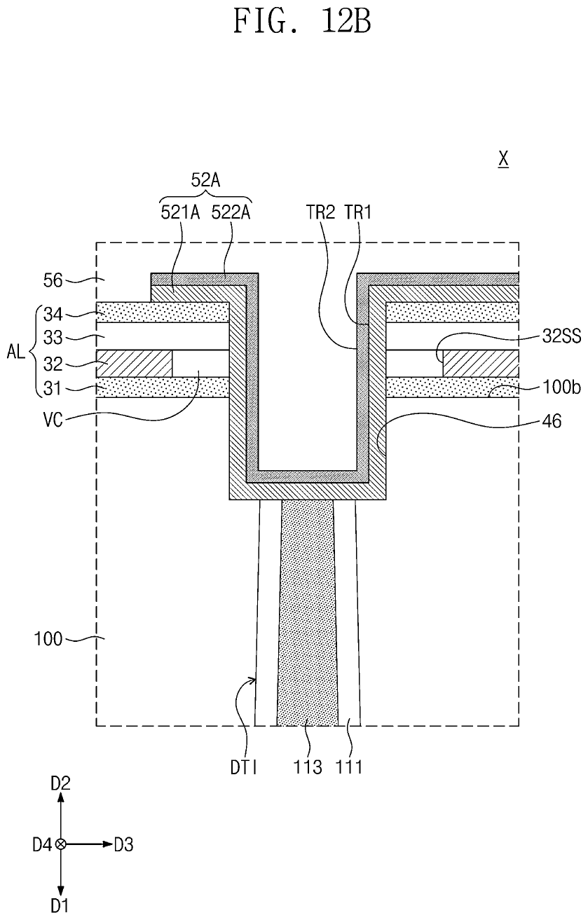

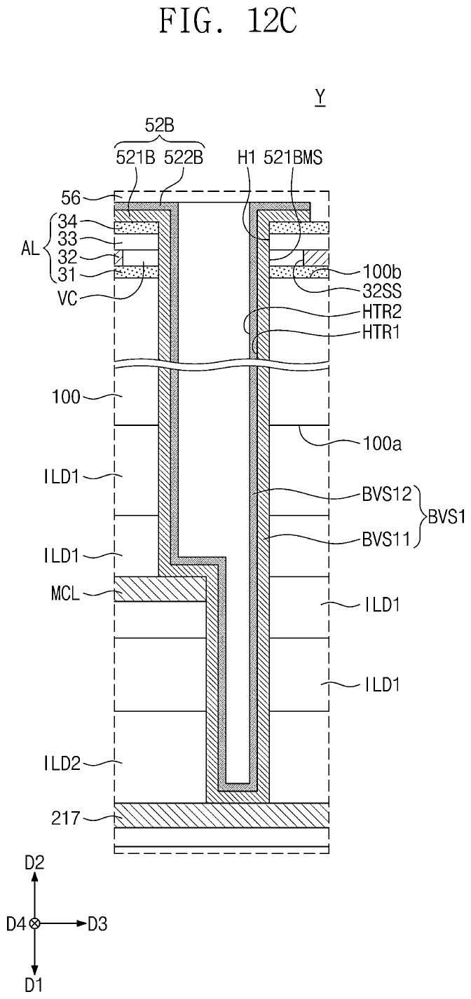

Referring to FIGS. 12A, 12B, and 12C, a conductive layer may be conformally stacked on the third dielectric layer 34, and the conductive layer may be etched to form an optical black liner 52p, a contact conductive pattern 52A, a connection conductive pattern 52B, a first backside via pattern BVS1, a second backside via pattern BVS2, a pad conductive pattern 52C, and via connection lines 52D.

In this step, the conductive layer may be stacked in a state where the first, second, third, and fourth recesses RS1, RS2, RS3, and RS4 are empty. In an embodiment, the conductive layer may be stacked in a state where the first to fourth recesses RS1-RS4 include a dielectric material. In an embodiment, the conductive layer may be stacked in a state where at least one of the first to fourth recesses RS1-RS4 is empty and remaining ones of the first to fourth recesses RS1-RS4 include a dielectric material.

Thus, a contact break VC1, a first via break VC2, a pad break VC3, and a second via break VC4 (collectively referred to as “VC” in FIGS. 12A-12C) may be formed.

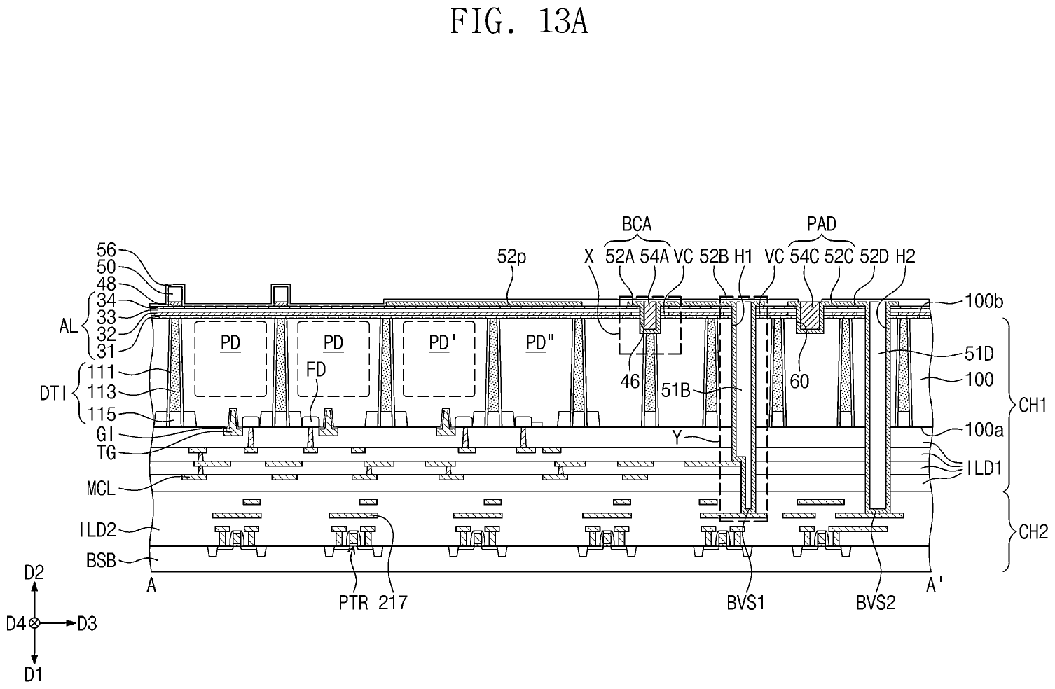

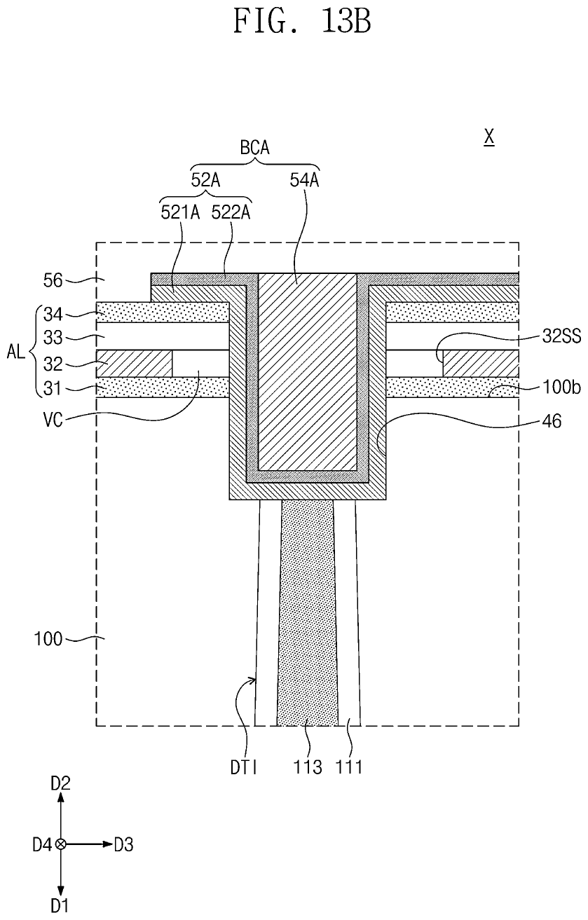

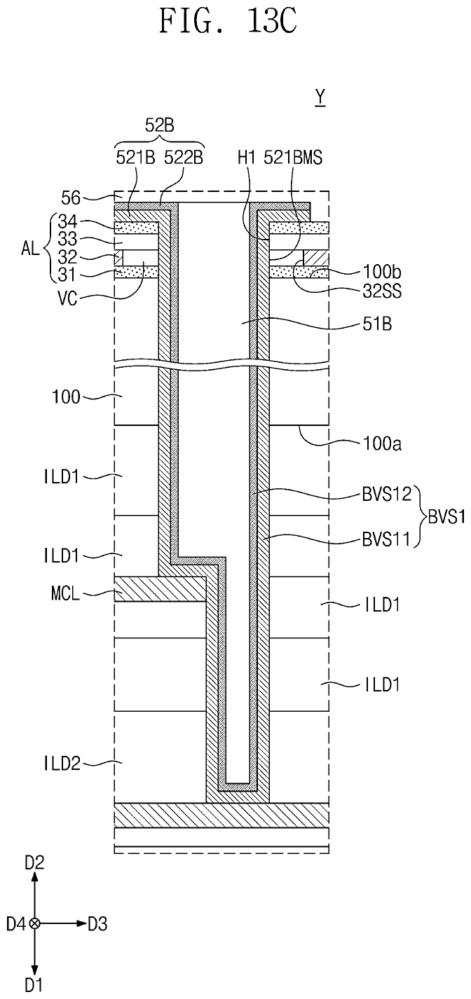

Referring to FIGS. 13A, 13B, and 13C, a light-shield layer and a low-refractive layer may be sequentially conformally stacked on the third dielectric layer 34, and the light-shield layer and the low-refractive layer may be etched to form a light-shield pattern 48 and a low-refractive pattern 50.

A protection layer 56 may be formed to cover the third dielectric layer 34, the optical black liner 52p, the contact conductive pattern 52A, the connection conductive pattern 52B, the first backside via pattern BVS1, the second backside via pattern BVS2, the pad conductive pattern 52C, the via connection lines 52D, the light-shield pattern 48, and the low-refractive pattern 50.

Afterwards, referring back to FIG. 4, color filters CF1 and CF2 may be formed between the low-refractive patterns 50. An optical black pattern CFB may be formed on the optical black liner 52p. Microlenses ML may be formed on the color filters CF1 and CF2. A lens residual layer MLR may be formed on the optical black pattern CFB. On the pad region PR, an opening 35 may be formed in the lens residual layer MLR to expose the backside conductive pad PAD. An image sensor may be fabricated as shown in FIGS. 3 and 4.

According to the disclosure, an image sensor may include a break, which includes an empty space or a dielectric material, disposed between a backside contact and a high-refractive layer. In this case, the backside contact and the high-refractive layer may be spaced apart from each other, and an electrical short structure may be formed.

According to the disclosure, as the break is disposed between the backside contact and the high-refractive layer, an electrical leakage path may be interrupted when a high-refractive material is applied to a bottom antireflective layer (BARL), and thus the image sensor may have improved performance. In addition, since an additional process step for avoiding a leakage current is not required, a manufacturing cost of the image sensor may be reduced.

The aforementioned description provides some example embodiments for explaining the disclosure. Therefore, the disclosure are not limited to the embodiments described above, and it will be understood by one of ordinary skill in the art that variations in form and detail may be made therein without departing from the spirit and essential features of the disclosure.

What is claimed is:

1. An image sensor, comprising:
a substrate that has a first surface and a second surface that are opposite to each other, the substrate including a pixel array area and an edge area;
an antireflection structure on the second surface;
a substrate isolation part in the substrate, the substrate isolation part separating the substrate;
a microlens on the antireflection structure; and
a backside contact in a backside contact trench, the backside contact trench penetrating the antireflection structure, the backside contact being in contact with the substrate isolation part,
wherein the backside contact includes:
a contact conductive pattern on a sidewall of the backside contact trench; and
a contact metal pattern on the contact conductive pattern, and
wherein the antireflection structure includes:
a first dielectric layer;
a high-refractive layer on the first dielectric layer; and
a contact break between the high-refractive layer and the backside contact.

2. The image sensor of claim 1, wherein the high-refractive layer includes titanium oxide, and
wherein the contact break includes an empty space therein.

3. The image sensor of claim 1, wherein a refractive index of the substrate is greater than a refractive index of the high-refractive layer.

4. The image sensor of claim 1, wherein the antireflection structure includes:
a second dielectric layer on the high-refractive layer; and
a third dielectric layer on the second dielectric layer, and
wherein a refractive index of the second dielectric layer is less than a refractive index of the high-refractive layer and is about 1 or greater than 1.

5. The image sensor of claim 1, wherein the high-refractive layer includes titanium oxide, and
wherein the contact break includes SiO₂ or Al₂O₃.

6. The image sensor of claim 1, further comprising:
a first interlayer dielectric layer on the first surface of the substrate;
a first interlayer wiring line in the first interlayer dielectric layer;
a second interlayer dielectric layer on or below the first interlayer dielectric layer;
a second interlayer wiring line in the second interlayer dielectric layer;
a first backside via pattern that penetrates the antireflection structure on the edge area; and
a connection conductive pattern that continuously connects the first backside via pattern and the contact conductive pattern to each other,
wherein the first backside via pattern electrically connects the first interlayer wiring line and the second interlayer wiring line to each other.

7. The image sensor of claim 1, further comprising:
a first backside via pattern that penetrates the antireflection structure on the edge area; and
a first via break between the high-refractive layer and the first backside via pattern.

8. The image sensor of claim 1, wherein the contact break has a contact break lateral surface in contact with the contact conductive pattern, the contact break lateral surface including a curved surface.

9. An image sensor, comprising:
a substrate that has a first surface and a second surface that are opposite to each other, the substrate including a pixel array area and an edge area;
an antireflection structure on the second surface;
a microlens on the antireflection structure;
a first backside via pattern that penetrates the antireflection structure and the substrate on the edge area;
a first interlayer dielectric layer on the first surface of the substrate;
a first interlayer wiring line in the first interlayer dielectric layer;
a second interlayer dielectric layer on or below the first interlayer dielectric layer; and
a second interlayer wiring line in the second interlayer dielectric layer,
wherein the antireflection structure includes:
a first dielectric layer;
a high-refractive layer on the first dielectric layer; and
a first via break between the high-refractive layer and the first backside via pattern.

10. The image sensor of claim 9, wherein the first backside via pattern includes a first via protrusion that protrudes toward the high-refractive layer.

11. The image sensor of claim 9, wherein a refractive index of the high-refractive layer is between about 2.0 to about 2.3.

12. The image sensor of claim 9, further comprising:
a substrate isolation part in the substrate, the substrate isolation part separating the substrate; and
a backside contact in a backside contact trench the backside contact trench penetrating the antireflection structure, the backside contact being in contact with the substrate isolation part,
wherein the backside contact includes:
a contact conductive pattern on a sidewall of the backside contact trench; and
a contact metal pattern on the contact conductive pattern,
wherein the antireflection structure further includes a contact break that is between the high-refractive layer and a sidewall of the contact conductive pattern.

13. The image sensor of claim 12, wherein the backside contact includes a contact protrusion that protrudes toward the contact break.

14. The image sensor of claim 12, further comprising a connection conductive pattern that continuously connects the first backside via pattern and the contact conductive pattern to each other.

15. The image sensor of claim 9, wherein the high-refractive layer includes titanium oxide, and
wherein the via break includes an empty space.

16. The image sensor of claim 9, wherein the via break includes SiO₂ or Al₂O₃.

17. The image sensor of claim 9, further comprising a backside contact in a backside contact trench, the backside contact trench penetrating the antireflection structure,
wherein the antireflection structure further includes a second dielectric layer on the high-refractive layer, and
wherein the second dielectric layer is continuously interposed between the backside contact and the first backside via pattern.

18. An image sensor, comprising:
a substrate that has a first surface and a second surface that are opposite to each other, the substrate including a pixel array area and an edge area;
a transfer gate on the first surface;
an antireflection structure on the second surface;
a substrate isolation part in the substrate, the substrate isolation part separating the substrate;
a microlens on the antireflection structure; and
a backside contact in a backside contact trench, the backside contact trench penetrating the antireflection structure, the backside contact being in contact with the substrate isolation part,
wherein the backside contact includes:
a contact conductive pattern on a sidewall of the backside contact trench; and
a contact metal pattern on the contact conductive pattern,
wherein the antireflection structure includes:
a first dielectric layer;
a high-refractive layer on the first dielectric layer; and
a contact break between the high-refractive layer and the backside contact, and
wherein the backside contact includes a contact protrusion that protrudes toward the contact break.

19. The image sensor of claim 18, wherein the contact break includes an empty space therein.

20. The image sensor of claim 18, wherein the contact conductive pattern includes:
a first contact conductive pattern in contact with the substrate; and
a second contact conductive pattern on the first contact conductive pattern,
wherein the first contact conductive pattern includes titanium, and
wherein the second contact conductive pattern includes tungsten.
